(19) United States
(12) Patent Application Publication
(10) Pub. No.: US 2024/0203890 A1
(43) Pub. Date: Jun. 20, 2024

(54) POWER MODULE AND METHOD FOR PRODUCING A POWER MODULE

(71) Applicant: Robert Bosch GmbH, Stuttgart (DE)

(72) Inventor: Irfan AYDOGMUS, NUERTINGEN (DE)

(21) Appl. No.: 18/533,809

(22) Filed: Dec. 8, 2023

(30) Foreign Application Priority Data
Dec. 14, 2022 (DE) 10 2022 213 634.9

(51) Int. Cl. H01L 23/538; H01L 21/56; H01L 23/31; H01L 25/00; H01L 25/07; H01L 23/00

(52) U.S. Cl. CPC H01L 23/5386; H01L 21/565; H01L 23/3107; H01L 25/072; H01L 25/50; H01L 24/48; H01L 2224/48227

(57) ABSTRACT

A power module. The power module includes a first circuit carrier, on the upper side of which a first conductor structure, having two internal contact regions on each of which a first power terminal of at least one first semiconductor switch is arranged and contacted, and a second conductor structure, having two internal contact regions on each of which a first power terminal of at least one second semiconductor switch is arranged and contacted, are formed, wherein second power terminals of the first semiconductor switches are in each case contacted with a common third internal contact region of the second conductor structure, wherein second power terminals of the second semiconductor switches are in each case contacted with a common internal contact region of a third conductor structure, wherein at least two further circuit carriers are arranged spatially in parallel above the first circuit carrier.

### FIELD

The present invention relates to a power module, in particular for providing a phase current for an electric motor of a vehicle. The present invention also relates to a method for producing such a power module.

### BACKGROUND INFORMATION

German Patent No. DE 10 2014 219 998 B4 describes a power module, in particular for providing a phase current for an electric motor. The power module comprises a circuit carrier having a surface, at least two first contact areas on the surface, and at least two first power transistors, which each have a base contact area. In each case, a first power transistor of the at least two first power transistors is arranged directly on one of the first contact areas and is electrically conductively connected directly to the respective first contact area via its base contact area. In addition, the power module comprises a second contact area on the surface and at least two second power transistors, which each have a base contact area. The at least two second power transistors are arranged directly on the second contact area and are electrically conductively connected directly to the second contact area via their respective base contact areas. Furthermore, the power module comprises at least two third contact areas on the surface, wherein the at least two second power transistors each have a further contact area on their sides facing away from the surface of the circuit carrier, and in each case a second power transistor of the at least two second power transistors is electrically conductively connected via its further contact area to one of the at least two third contact areas in each case. The at least two first contact areas and the at least two third contact areas are arranged alternately one after the other in a longitudinal direction of the power module, and the second contact area is arranged next to the at least two first contact areas and the at least two third contact areas, wherein the second contact area has at least two contact regions, wherein in each case one of the at least two contact regions is located next to one of the at least two first power transistors. The at least two first power transistors each have a further contact area on their sides facing away from the surface of the circuit carrier, and in each case a first power transistor of the at least two first power transistors is electrically conductively connected via its further contact area to the in each case one contact region, located next to it, of the at least two contact regions of the second contact area. In this case, the at least two contact regions of the second contact area and the at least two second power transistors are arranged alternately one after the other in the longitudinal direction.

European Patent No. EP 2 418 925 B1 describes electrical contacting between a flexible film, which has at least one conductor track, and at least one electrical contact of a sensor or a control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

A power module, in particular for providing a phase current for an electric motor of a vehicle having features of the present invention, may have the advantage that the load current is distributed symmetrically to oppositely arranged first semiconductor switches if a short circuit occurs in one of the second semiconductor switches, or is distributed to oppositely arranged second semiconductor switches if a short circuit occurs in one of the first semiconductor switches. By distributing the load current to at least two semiconductor switches, a situation in which a single semiconductor switch must “carry” the current load “alone” can advantageously be prevented. This means that by contacting power terminals of the two oppositely arranged semiconductor switches at a common internal contact region, the load current can be distributed uniformly to the two oppositely arranged semiconductor switches in the event of a short circuit, so that all the semiconductor switches can be supplied with current in the same way, or the utilization can be made symmetrical.

Example embodiments of the present invention provide a power module having a first circuit carrier, which has an electrically insulating layer. On an upper side of the electrically insulating layer at least one first conductor structure, having two internal contact regions which are arranged mirror-symmetrically to a central longitudinal axis and on each of which a first power terminal of at least one first semiconductor switch is arranged and contacted, and at least one second conductor structure, having two internal contact regions which are arranged mirror-symmetrically to the central longitudinal axis and on each of which a first power terminal of at least one second semiconductor switch is arranged and contacted, are formed. Second power terminals of the first semiconductor switches are in each case contacted with a common third internal contact region of the at least one second conductor structure, which third internal contact region is arranged between the first internal contact region and the second internal contact region of the at least one first conductor structure. Second power terminals of the second semiconductor switches are in each case contacted with a common internal contact region of at least one third conductor structure, which internal contact region is arranged between the first internal contact region and the second internal contact region of the at least one second conductor structure. In this case, at least two further circuit carriers are arranged spatially in parallel above the first circuit carrier and each have at least one internal contact region, at which control terminals of the first and second semiconductor switches are contacted, and at least one external contact region, which can be electrically connected to an external control circuit. The at least two further circuit carriers are each designed as strip-shaped flexible printed circuit boards and are arranged at opposite edges of the first circuit carrier.

In addition, a method for producing such a power module is provided according to the present invention. According to an example embodiment of the present invention, in the method, a first circuit carrier, the layout of which is mirror-symmetrical to a central longitudinal axis and which has an electrically insulating layer, on the upper side of which at least one first conductor structure, having two internal contact regions which are arranged mirror-symmetrically to a central longitudinal axis, and at least one second conductor structure, having two internal contact regions which are arranged mirror-symmetrically to the central longitudinal axis, are formed, and two further circuit carriers, which each have at least one internal contact region and at least one external contact region and are designed as strip-shaped flexible printed circuit boards, and at least two first semiconductor switches and at least two second semiconductor switches, are provided. In addition, first power terminals of the at least two first semiconductor switches are each arranged and electrically contacted on one of the two internal contact regions of the at least one first conductor structure that are arranged mirror-symmetrically to the central longitudinal axis. Furthermore, first power terminals of the at least two second semiconductor switches are each arranged and electrically contacted on one of the two internal contact regions of the at least one second conductor structure that are arranged mirror-symmetrically to the central longitudinal axis. Second power terminals of the first semiconductor switches are in each case contacted with a common third internal contact region of the at least one second conductor structure, which third internal contact region is arranged between the first internal contact region and the second internal contact region of the at least one first conductor structure. Second power terminals of the second semiconductor switches are in each case contacted with a common internal contact region of at least one third conductor structure, which internal contact region is arranged between the first internal contact region and the second internal contact region of the at least one second conductor structure. In this case, the two further circuit carriers are arranged spatially in parallel above the first circuit carrier at opposite edge regions and are connected to the first circuit carrier via soldered connections or welded connections or adhesive connections or sintered connections. Control terminals of the first and second semiconductor switches are each contacted with at least one internal contact region of the two further circuit carriers.

According to an example embodiment of the present invention, the first circuit carrier can be designed, for example, as a DBC (direct bonded copper) substrate or as an AMB (active metal bonding) substrate. The semiconductor switches can, for example, be configured as field effect transistors, so that drain terminals of the semiconductor switches can each correspond to a first power terminal. Source terminals of the semiconductor switches can correspond to second power terminals. If bipolar transistors are used as semiconductor switches, collector terminals can correspond to the first power terminals, and emitter terminals can correspond to the second power terminals of the semiconductor switches. A control terminal can be understood to mean, for example, a gate terminal or a Kelvin source terminal of a field effect transistor or a base terminal of a bipolar transistor. Due to the design as flexible circuit boards, which are also referred to as flexible film, the at least two further circuit carriers can be produced cost-effectively.

As a result of the measures and developments disclosed herein, advantageous improvements of the power module and of the method for producing such a power module are possible.

According to an example embodiment of the present invention, it is particularly advantageous that the at least one first conductor structure can be contacted via at least one external contact region with a first supply terminal, and the at least one second conductor structure can be contacted via at least one external contact region with a load terminal, and the at least one third conductor structure can be contacted via at least one external contact region with a second supply terminal. The at least one external contact region of the at least one first conductor structure and the at least one external contact region of the at least one third conductor structure can thus be arranged on a common first end region of the first circuit carrier. The at least one external contact region of the at least one second conductor structure of the first circuit carrier can be arranged on a second end region, opposite the first end region, of the first circuit carrier. A first busbar for connecting the power module to the positive first supply terminal and a second busbar for connecting the power module to the negative second supply terminal can thereby be applied to the same side of the circuit carrier. This makes it possible for the busbars for connecting the conductor structures to the supply terminals of the DC voltage supply to be arranged above one another. A third busbar for connecting the power module to the load terminal can be arranged on the opposite side of the power module. This enables simple contacting of the power module.

In a further advantageous embodiment of the power module of the present invention, the at least one first semiconductor switch, which is arranged on the second internal contact region of the at least one first conductor structure, can be oriented so as to be rotated by 180° relative to the at least one first semiconductor switch, which is arranged on the opposite first internal contact region of the at least one first conductor structure. The contacting of the second power terminals of the first semiconductor switches with the common third internal contact region of the at least one second conductor structure can thereby be simplified. In addition, the at least one second semiconductor switch, which is arranged on the second internal contact region of the at least one second conductor structure, can be oriented so as to be rotated by 180° relative to the at least one second semiconductor switch, which is arranged on the opposite first internal contact region of the at least one second conductor structure. Contacting the second power terminals of the second semiconductor switches with the common internal contact region of the at least one third conductor structure can thereby be simplified. The at least two first semiconductor switches can also be referred to as “high-side switches”, since they can preferably be looped in between the positive supply terminal and the load terminal. By arranging the at least two first semiconductor switches on two opposite internal contact regions of the at least one first conductor structure, two symmetrical groups of “high-side switches”, which can each comprise, for example, one, two, three or more first semiconductor switches, can be formed depending on the current load. In addition, leakage inductances can be reduced by the symmetrical arrangement of the first semiconductor switches. The at least two second semiconductor switches can also be referred to as “low-side switches”, since they can be looped in between the negative supply terminal and the load terminal. By arranging the at least two second semiconductor switches on two opposite internal contact regions of the at least one second conductor structure, two symmetrical groups of “low-side switches”, which can each comprise, for example, one, two, three or more second semiconductor switches, can be formed depending on the current load. In addition, leakage inductances can be reduced by the symmetrical arrangement of the second semiconductor switches. Due to the rotation by 180°, the second power terminal of the at least one first semiconductor switch of a first high-side switch group and the second power terminal of the at least one first semiconductor switch of a second high-side switch group face one another. In addition, the second power terminal of the at least one second semiconductor switch of a first low-side switch group and the second power terminal of the at least one second semiconductor switch of a second low-side switch group face one another. The desired symmetrical design of the first circuit carrier can thereby be easily implemented.

In an advantageous embodiment of the power module of the present invention, the second power terminals of the first semiconductor switches can each be contacted via at least one power connection with the third internal contact region of the at least one second conductor structure, and the second power terminals of the second semiconductor switches can each be contacted via at least one power connection with the internal contact region of the at least one third conductor structure. The at least one power connection can preferably be produced via suitable bonding wires. The number of power connections depends on the required current carrying capacity.

In a further advantageous embodiment of the power module of the present invention, the control terminals of the at least one first semiconductor switch, which is arranged on the first internal contact region of the at least one first conductor structure, and the control terminals of the at least one second semiconductor switch, which is arranged on the first internal contact region of the at least one second conductor structure, can each be contacted via signal connections with a common internal contact region of a first further printed circuit board. In addition, the control terminals of the at least one first semiconductor switch, which is arranged on the second internal contact region of the at least one first conductor structure, and the control terminals of the at least one second semiconductor switch, which is arranged on the second internal contact region of the at least one second conductor structure, can each be contacted via signal connections with a common internal contact region of a second further printed circuit board. The signal connections can be produced, for example, via suitable bonding wires.

In a further advantageous embodiment of the power module of the present invention, the layouts of the two further printed circuit boards can be identical, and the two further printed circuit boards can be arranged so as to be rotated by 180° relative to one another about a vertical axis at the opposite edges of the first circuit carrier. The internal contact regions of the two printed circuit boards can thereby each be arranged on an edge of the two further circuit carriers that faces the corresponding first and second semiconductor switches.

In a further advantageous embodiment of the power module of the present invention, a first external contact region of a first further circuit carrier can be designed to be electrically contacted with a first external contact device that has a contact region with multiple contact elements. A second external contact region of a second further circuit carrier can be designed to be electrically contacted with a second external contact device that has a contact region with multiple contact elements. The contact elements of the external contact regions of the two second circuit carriers can be connectable to the contact elements of the external contact devices via soldered connections or welded connections or adhesive connections or plug connections. In this case, the external contact devices can preferably be designed as flexible printed circuit boards.

Alternatively, the external contact devices can be designed as plug sockets or as plugs.

In a further advantageous embodiment of the power module of the present invention, the power module can be overmolded by an enclosure. In this case, the enclosure can in each case have a cut-out in the region of the external contact regions of the first circuit carrier so that the external contact regions of the first circuit carrier can be contacted. In regions of the at least one external contact region of the at least two further circuit carriers, an exposure can be made in each case in the enclosure so that the contact elements of the at least one external contact region of the at least two further circuit carriers are exposed and contactable. The enclosure can preferably be formed by a cured molding compound. Since the enclosure ensures good fixing of the semiconductor switches and of the further circuit carriers even at high temperatures, the service life of the semiconductor switches and of the electrical connections and contacts can be significantly increased. In addition, the semiconductor switches and the various electrical contacts and connections and the conductor structures can be protected from external influences by the enclosure. Furthermore, the enclosure allows easier handling of the enclosed power module, so that the power modules can easily be further processed and transported.

In an advantageous embodiment of the method for producing a power module according to the present invention, the populated and contacted power module can be inserted into a mold tool and overmolded with an enclosure in a molding process. During the molding process, the enclosure can be cut out by insert parts in the region of the external contact regions of the first circuit carrier so that the external contact regions of the first circuit carrier can be contacted after removal of the overmolded power module from the mold tool due to the cut-outs produced. In regions of the at least one external contact region of the two further circuit carriers, the enclosure can be exposed in each case so that the contact elements of the external contact regions of the further circuit carriers can be contacted through the exposure produced. In this case, the external contact regions of the two further circuit carriers can be exposed before removal of the overmolded power module from the mold tool. Alternatively, the external contact regions of the two further circuit carriers can be exposed after removal of the overmolded power module from the mold tool.

Because the individual contact elements of the at least one external contact region of the further circuit carriers are exposed after curing of the enclosure, the other components of the power module remain fluid-tightly enclosed by the enclosure and protected from external influences. The individual contact elements are preferably exposed by means of a laser beam. The exposed contact elements of the at least one external contact region of the further circuit carriers can then easily be electrically connected via corresponding signal lines to an evaluation and control unit and/or a control device, which can generate and output the control signals for actuating the semiconductor switches. Since the external contact regions of the various conductor structures that can be contacted with supply terminals or load terminals have a larger area, corresponding insert parts can be inserted into the tool in the region of the external contact regions of the first circuit carrier during the molding process, which insert parts cause corresponding cut-outs in the enclosure. As a result, the external contact regions of the first circuit carrier of the power module can easily be contacted with the positive supply terminal, the negative supply terminal, and the load terminal after the enclosure has cured.

Exemplary embodiments of the present invention are illustrated in the figures and explained in more detail in the following description. In the figures, identical reference signs denote components or elements which perform the same or analogous functions.

### BRIEF DESCRIPTION OF THE DRAWINGS

FIG. 1 shows a schematic plan view of an exemplary embodiment of a power module according to an example embodiment of the present invention without an enclosure.

FIG. 2 shows a schematic plan view of a first circuit carrier for the power module according to an example embodiment of the present invention from FIG. 1.

FIG. 3 shows a schematic plan view of the power module according to an example embodiment of the present invention from FIGS. 1 and 2 with an enclosure.

FIG. 4 shows a schematic flowchart of an exemplary embodiment of a method according to the present invention for producing the power module according to an example embodiment of the present invention from FIG. 1 to 3.

### DETAILED DESCRIPTION OF EXAMPLE EMBODIMENTS

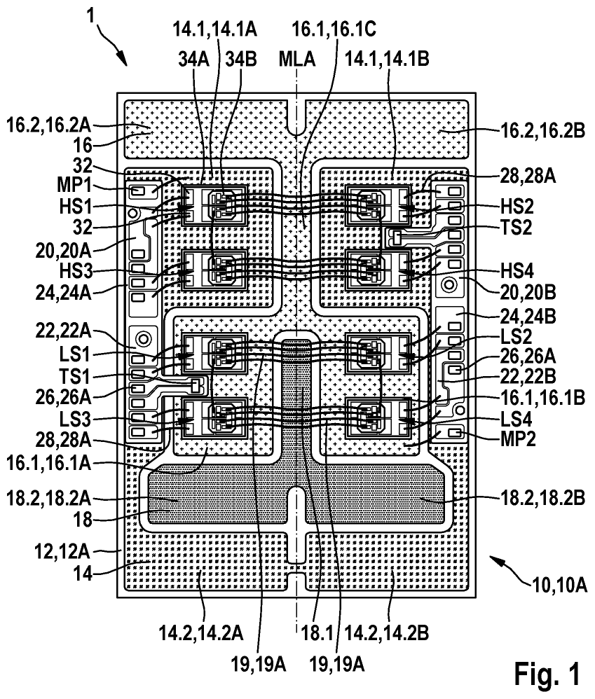

As can be seen from FIG. 1 to 3, the shown exemplary embodiment of a power module 1 according to the present invention comprises a first circuit carrier 10, which has an electrically insulating layer 12. On an upper side of the electrically insulating layer 12 are formed at least one first conductor structure 14 having two internal contact regions 14.1A, 14.1B that are arranged mirror-symmetrically to a central longitudinal axis MLA and on each of which a first power terminal 34A of at least one first semiconductor switch HS1 to HS4 is arranged and contacted, and at least one second conductor structure 16 having two internal contact regions 16.1A, 16.1B that are arranged mirror-symmetrically to the central longitudinal axis MLA and on each of which a first power terminal 34A of at least one second semiconductor switch LS1 to LS4 is arranged and contacted. Second power terminals 34B of the first semiconductor switches HS1 to HS4 are in each case contacted with a common third internal contact region 16.1C of the at least one second conductor structure 16, which third internal contact region is arranged between the first internal contact region 14.1A and the second internal contact region 14.1B of the first conductor structure 14. Second power terminals 34B of the second semiconductor switches LS1 to LS4 are in each case contacted with a common internal contact region 18.1 of at least one third conductor structure 18, which internal contact region is arranged between the first internal contact region 16.1A and the second internal contact region 16.1B of the at least one second conductor structure 16. In this case, at least two further circuit carriers 20 are arranged spatially parallel above the first circuit carrier 10 and each have at least one internal contact region 22, at which control terminals 32 of the first and second semiconductor switches HS1 to HS4, LS1 to LS4 are contacted, and at least one external contact region 24, which can be electrically connected to an external control circuit. The at least two further circuit carriers 20 are each designed as strip-shaped flexible printed circuit boards 20A, 20B and are arranged at opposite edges of the first circuit carrier 10.

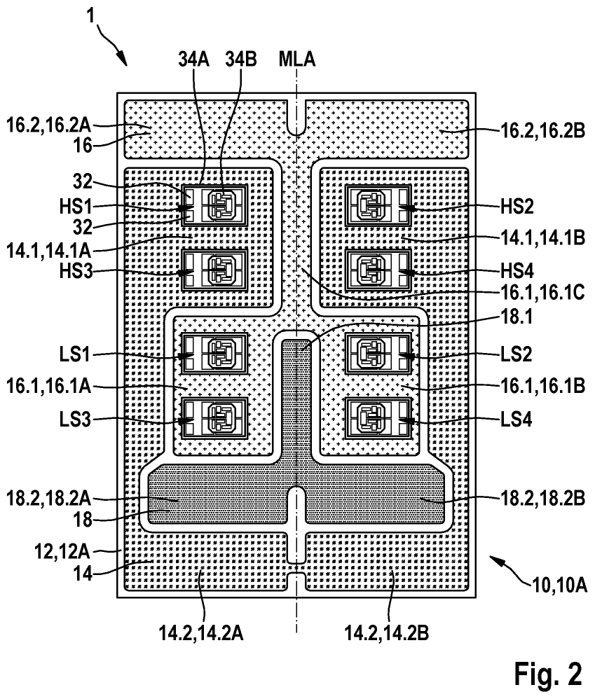

As can further be seen from FIGS. 1 and 2, in the shown exemplary embodiment of the power module 1, only a first conductor structure 14 and only a second conductor structure 16, and only a third conductor structure 18, which is designed as a ceramic layer, are formed on the insulating layer 12 on an upper side of the first circuit carrier 10. In addition, at least one metal layer (not shown in more detail) is arranged on the insulating layer 12 on the underside of the first circuit carrier 10, via which layer the lost heat of the semiconductor switches HS1 to HS4, LS1 to LS4 can be dissipated. In the exemplary embodiment shown, the first circuit carrier 10 is designed as an AMB substrate 10A (AMB: active metal bonding), and the semiconductor switches HS1 to HS4, LS1 to LS4 are designed as field effect transistors 30, so that drain terminals of the field effect transistors 30 each correspond to a first power terminal 34A of the semiconductor switches HS1 to HS4, LS1 to LS4, and source terminals of the field effect transistors 30 each correspond to a second power terminal 34B of the semiconductor switches HS1 to HS4, LS1 to LS4. The control terminals 32 of the semiconductor switches HS1 to HS4, LS1 to LS4 each correspond to a gate terminal or to a Kelvin source terminal of the respective field effect transistor 30. In addition, two further circuit carriers 20 are arranged spatially parallel above the first circuit carrier 10. In this case, a first further circuit carrier 20A with a first internal contact region 22A and a first external contact region 24A is arranged on a left-hand edge of the first circuit carrier 10 in the diagram. A second further circuit carrier 20B with a second internal contact region 22B and a second external contact region 24B is arranged on a right-hand edge of the first circuit carrier 10 in the diagram. The layouts of the two further circuit carriers 20 are identical, wherein the second further circuit carrier 20B is rotated by 180° about a vertical axis relative to the first further circuit carrier 20A. As can further be seen from FIG. 1, the two external contact regions 24A, 24B are each arranged at the outer edge of the two circuit carriers 20. The two internal contact regions 22A, 22B are each arranged at the inner edge of the two circuit carriers. The two further circuit carriers 20 are connected to the first circuit carrier 10 via soldered connections or welded connections or adhesive connections or sintered connections.

As can further be seen from FIGS. 1 and 2, the first conductor structure 14 is U-shaped, wherein outer legs of the U-shaped first conductor structure 14 are arranged on an edge on the left in the diagram and on an edge on the right in the diagram, of the first circuit carrier 10. A connecting web of the first conductor structure 14, which connects the two legs of the first conductor structure 14 to one another, has a central narrowed portion and is arranged on an edge of the first circuit carrier 10 at the bottom in the diagram. In addition, an open end of the legs of the first conductor structure 14 each have a widened portion, wherein a widened portion of the left leg of the first conductor structure 14 forms a first internal contact region 14.1A of the first conductor structure 14, and a widened portion of the right leg of the first conductor structure 14 forms a second internal contact region 14.1B of the first conductor structure 14. In addition, a portion, on the left in the diagram, of the connecting web of the first conductor structure 14 forms a first external contact region 14.2A of the first conductor structure 14, and a portion, on the right in the diagram, of the connecting web of the first conductor structure 14 forms a second external contact region 14.2B of the first conductor structure 14.

As can further be seen from FIGS. 1 and 2, the second conductor structure 16 is H-shaped and rotated by 90° in the clockwise direction, wherein a longitudinal beam, at the top in the diagram, of the H-shaped second conductor structure 16 is arranged on an edge, at the top in the diagram, of the first circuit carrier 10. As can further be seen from FIGS. 1 and 2, the third conductor structure 18 is T-shaped and rotated by 180° in the clockwise direction, so that a cross beam of the T-shaped third conductor structure 18 runs parallel to the connecting web of the U-shaped first conductor structure 14 and has a central narrowed portion. A longitudinal beam, at the bottom in the diagram, of the H-shaped second conductor structure 16 is arranged between the cross beam of the T-shaped third conductor structure 18 and the two internal contact regions 14.1A, 14.1B of the first conductor structure 14 and has a central narrowed portion, in which a longitudinal beam of the T-shaped third conductor structure 18 runs. In this case, a portion, on the left in the diagram, of the lower longitudinal beam of the H-shaped second conductor structure 16 forms a first internal contact region 16.1A of the second conductor structure 16, and a portion, on the right in the diagram, of the lower longitudinal beam of the H-shaped second conductor structure 16 forms a second internal contact region 16.1B of the second conductor structure 16. A connecting web of the second conductor structure 16, which connects the two longitudinal beams of the second conductor structure 16 to one another, runs along the central longitudinal axis MLA of the first circuit carrier 10 and forms a third internal contact region 16.1C of the second conductor structure 16. The longitudinal beam of the T-shaped third conductor structure 18, which runs along the central longitudinal axis MLA of the first circuit carrier 10, forms an internal contact region 18.1 of the third conductor structure 18. In addition, a portion, on the left in the diagram, of the cross beam of the third conductor structure 18 forms a first external contact region 18.2A of the third conductor structure 18, and a portion, on the right in the diagram, of the cross beam of the third conductor structure 18 forms a second external contact region 18.2B of the third conductor structure 18. The longitudinal beam, at the top in the diagram, of the H-shaped second conductor structure 16 has a central narrowed portion. In this case, a portion, on the left in the diagram, of the upper longitudinal beam of the H-shaped second conductor structure 16 forms a first external contact region 16.2A of the second conductor structure 16, and a portion, on the right in the diagram, of the upper longitudinal beam of the H-shaped second conductor structure 16 forms a second external contact region 16.2B of the second conductor structure 16.

As can also be seen from FIG. 1 to 3, the two external contact regions 14.2A, 14.2B of the first conductor structure 14 and the two external contact regions 18.2A, 18.2B of the third conductor structure 18 are arranged on a common first, here lower end region of the first circuit carrier 10, wherein the two external contact regions 18.2A, 18.2B of the third conductor structure 18 are offset upward relative to the two external contact regions 14.2A, 14.2B of the first conductor structure 14. The two external contact regions 16.2A, 16.2B of the second conductor structure 16 are arranged on a second, here upper end region of the first circuit carrier 10, opposite the first end region. The first conductor structure 14 can be contacted via the two external contact regions 14.2A, 14.2B with a first, here positive supply terminal. The second conductor structure 16 can be contacted via the two external contact regions 16.2A, 16.2B with a load terminal. The third conductor structure 18 can be contacted via the two external contact regions 18.2A, 18.2B with a second, here negative supply terminal.

As can further be seen from FIGS. 1 and 2, in the shown exemplary embodiment of the power module 1, four first semiconductor switches HS1 to HS4, each having a first power terminal 34A designed as a contact area, are arranged and contacted on the at least one internal contact region 14.1 of the first conductor structure 14. A second power terminal 34B of the four first semiconductor switches HS1 to HS4 is in each case contacted via four power connections 19 designed as power bonding wires 19A with the third internal contact region 16.1C of the second conductor structure 16, which contact region is formed between the first internal contact region 14.1A and the second internal contact region 14.1B of the first conductor structure 14. In this case, two first semiconductor switches HS1, HS3 are arranged and contacted on the first internal contact region 14.1A of the first conductor structure 14 and form a first high-side switch group. Two first semiconductor switches HS2, HS4 are likewise arranged and contacted on the opposite second internal contact region 14.1B of the first conductor structure 14 and form a second high-side switch group. In addition, the first semiconductor switches HS2, HS4 arranged on the second internal contact region 14.1B of the first conductor structure 14 are oriented rotated by 180° relative to the first semiconductor switches HS1, HS3 arranged on the opposite first internal contact region 14.1A of the first conductor structure 14, so that the second power terminals 34B of the first semiconductor switches HS1, HS3 of the first high-side switch group face the second power terminals 34B of the first semiconductor switches HS2, HS4 of the second high-side switch group.

As can further be seen from FIGS. 1 and 2, in the shown exemplary embodiment of the power module 1, four second semiconductor switches LS1 to LS4, each having a first power terminal 34A designed as a contact area, are arranged and contacted on the at least one internal contact region 16.1 of the second conductor structure 16. A second power terminal 34B of the four second semiconductor switches LS1 to LS4 is in each case contacted via four power connections 19 designed as power bonding wires 19A with the internal contact region 18.1 of the third conductor structure 18, which contact region is formed between the first internal contact region 16.1A and the second internal contact region 16.1B of the second conductor structure 16. Two second semiconductor switches LS1, LS3 are arranged and contacted on the first internal contact region 16.1A of the second conductor structure 16 and form a first low-side switch group. Two second semiconductor switches LS2, LS4 are likewise arranged and contacted on the opposite second internal contact region 16.1B of the second conductor structure 16 and form a second low-side switch group. In addition, the second semiconductor switches LS2, LS4 arranged on the second internal contact region 16.1B of the second conductor structure 16 are oriented rotated by 180° relative to the second semiconductor switches LS1, LS3 arranged on the opposite first internal contact region 16.1A of the second conductor structure 16, so that the second power terminals 34B of the second semiconductor switches LS1, LS3 of the first low-side switch group face the second power terminals 34B of the second semiconductor switches LS2, LS4 of the second low-side switch group.

As can also be seen from FIG. 1, two load current paths result when high-side switches HS1 to HS4 are activated. In this case, a first high-side load current flows from the first external contact region 14.2A of the first conductor structure 14A, which contact region is electrically connected to the positive supply terminal (not shown), to the first high-side switch group. There, the first high-side load current is distributed to the two high-side switches HS1, HS3 of the first high-side switch group and then flows through the two high-side switches HS1, HS3 and the power connections 19 to the third internal contact region 16.1C of the second conductor structure 16. Analogously, a second high-side load current flows from the second external contact region 14.2B of the first conductor structure 14, which contact region is electrically connected to the positive supply terminal (not shown), to the second high-side switch group. There, the second high-side load current is distributed to the two high-side switches HS2, HS4 of the second high-side switch group and then flows through the two high-side switches HS2, HS4 and the power connections 19 to the third internal contact region 16.1C of the second conductor structure 16. There, the two high-side load currents add up to a total load current, which is then distributed to the two external contact regions 16.2A, 16.2B of the second power conductor structure 16 of the first circuit carrier 10, which are connected to the connected load. If one of the four low-side switches LS1 to LS4 has a short circuit, then the second conductor structure 16 is short-circuited to the negative supply terminal, so that the increased load current does not flow via the two external contact regions 16.2A, 16.2B of the second power conductor structure 16 to the load, but via the two external contact regions 18.2A, 18.2B of the third power conductor structure 18 to the negative supply terminal (not shown). The increased load current relates in particular to the two lower high-side switches HS3, HS4, since these are spatially closer to the short circuit. Since the increased load current is distributed to two high-side switches HS2, HS4 and does not load only one of the high-side switches HS2, HS4, damage can be prevented and the vehicle can be brought into a safe state.

As can further be seen from FIG. 1, two load current paths likewise result when low-side switches LS1 to LS4 are activated. In this case, a first low-side load current flows from the external contact regions 16.2A, 16.2B of the second conductor structure 18, which are electrically connected to the load terminal (not shown), along the connecting web of the second power conductor structure 16, to the first low-side switch group. There, the first low-side load current is distributed to the two low-side switches LS1, LS3 of the first low-side switch group and then flows through the two low-side switches LS1, LS3 to the internal contact region 18.1 of the third conductor structure 18. Analogously, a second low-side load current flows from the external contact regions 16.2A, 16.2B of the second conductor structure 18, which are electrically connected to the load terminal (not shown), along the connecting web of the second power conductor structure 16, to the second low-side switch group. There, the second low-side load current is distributed to the two low-side switches LS2, LS4 of the second low-side switch group and then flows through the two low-side switches LS2, LS4 to the internal contact region 18.1 of the third conductor structure 18. There, the two low-side load currents add up to a total load current, which is then distributed to the two external contact regions 18.2A, 18.2B of the third power conductor structure 18 of the first circuit carrier 10, which are connected to the negative supply terminal. If one of the four high-side switches HS1 to HS4 has a short circuit, then the second conductor structure 16 is short-circuited to the positive supply terminal, so that an increased load current leads via the four low-side switches LS1 to LS4 to the internal contact region 18.1 of the third power conductor structure 18 and thus to the negative supply terminal (not shown). The increased load current relates in particular to the two upper low-side switches LS1, LS2, since these are spatially closer to the short circuit. Since the increased load current is distributed to two low-side switches LS1, LS2 and does not load only one of the low-side switches LS1, LS2, damage can be prevented and the vehicle can be brought into a safe state.

As can also be seen from FIG. 1, the control terminals 32 of the first semiconductor switches HS1, HS3 arranged on the first internal contact region 14.1A of the first conductor structure 14 and the control terminals of the second semiconductor switches LS1, LS3 arranged on the first internal contact region 16.1A of the second conductor structure 16 are each contacted with the common first internal contact region 22A of the first further circuit carrier 20A via signal connections 28 designed as signal bonding wires 28A. The control terminals 32 of the first semiconductor switches HS2, HS4 arranged on the second internal contact region 14.1B of the first conductor structure 14 and the control terminals of the second semiconductor switches LS2, LS4 arranged on the second internal contact region 16.1B of the second conductor structure 16 are contacted with the common second internal contact region 22B of the second further circuit carrier 20B via signal connections 28 designed as signal bonding wires 28A. In addition, the first external contact region 24A of the first further circuit carrier 20A has a first measuring point MP1 at an upper end in the diagram, via which first measuring point a potential of the first conductor structure 14 can be tapped. In addition, the first further circuit carrier 20A has a first lug which projects into the first internal contact region 16.1A of the second conductor structure 16 and on which a first temperature sensor TS1 is arranged, the measured value of which is made available via the first external contact region 24A. Furthermore, the second external contact region 24A of the second further circuit carrier 20B has a second measurement point MP2 at a lower end in the diagram, via which a potential of the second conductor structure 16 can be tapped. In addition, the second further circuit carrier 20B has a second lug which projects into the second internal contact region 14.1B of the first conductor structure 14 and on which a second temperature sensor TS2 is arranged, the measured value of which is made available via the second external contact region 24B.

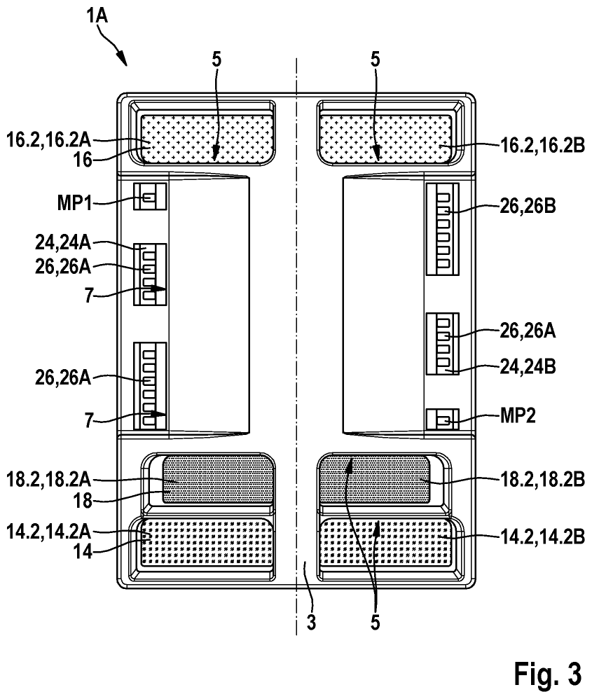

As can further be seen from FIG. 3, the power module 1 is overmolded by an enclosure 3, wherein the enclosure 3 of the overmolded power module 1A has in each case a cut-out 5 in the region of the external contact regions 14.2, 16.2, 18.2 of the first circuit carrier 10. The first external contact region 14.2A and the second external contact region 14.B of the first conductor structure 14 and the first external contact region 16.2A and the second external contact region 16.2B of the second conductor structure 16 and the first external contact region 18.2A and the second external contact region 18.2B of the third conductor structure 18 of the first circuit carrier 10 can thus be contacted. In the region of the at least one external contact region 24 of the first further circuit carrier 20A and of the at least one external contact region 24 of the second further circuit carrier 20A, an exposure 7 is made in the enclosure 3 in each case, so that the contact elements 26, in the form of spacer elements 26A, of the first external contact region 24A of the first further circuit carrier 20A and the contact elements 26, in the form of spacer elements 26A, of the second external contact region 24B of the second further circuit carrier 20B are exposed and contactable.

For the electrical connection of the external contact regions 24A, 24B to an evaluation and control unit (not shown) or a control device, which generate and output the control signals for actuating the semiconductor switches HS1 to HS4, LS1 to LS4, external contact devices (not shown in detail) can be used. The external contact devices can, for example, be designed as a flexible printed circuit board, which comprises a contact region and multiple contact elements. In this case, the contact elements of the respective external contact device are electrically contacted via welded connections to the contact elements 26 of the corresponding external contact regions 24A, 24B of the two further circuit carriers 20. Alternatively, the electrical contacting can take place via soldered connections or adhesive connections or plug connections. Alternatively, the external contact device can also be designed as a plug socket or as a plug.

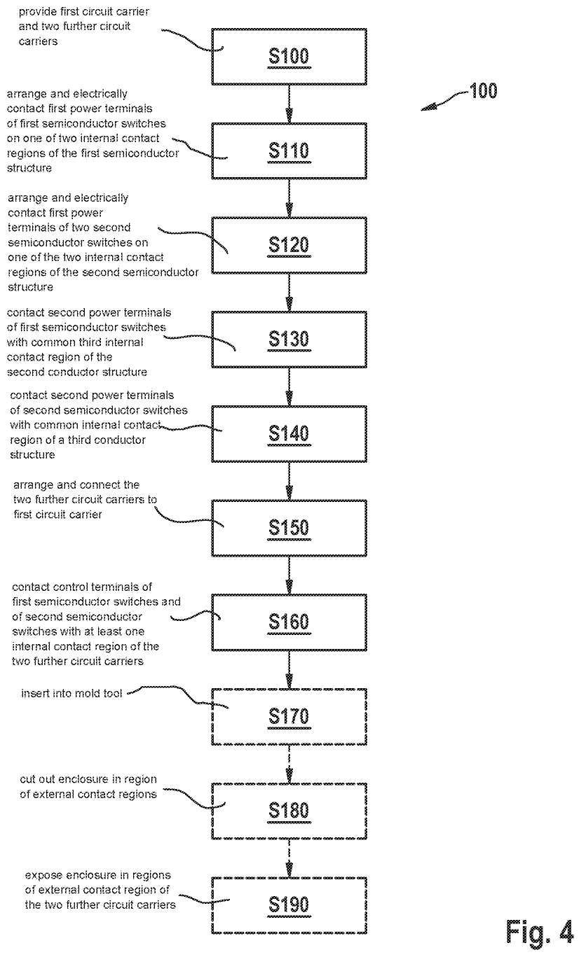

As can further be seen from FIG. 4, the illustrated exemplary embodiment of a method 100 according to the present invention for producing the power module 1 comprises a step S100, in which a first circuit carrier 10, the layout of which is mirror-symmetrical to a central longitudinal axis MLA and which has an electrically insulating layer 12, on the upper side of which are formed at least one first conductor structure 14 with two internal contact regions 14.1A, 14.1B arranged mirror-symmetrically to a central longitudinal axis MLA and at least one second conductor structure 16 with two internal contact regions 16.1A, 16.1B arranged mirror-symmetrically to the central longitudinal axis MLA, and two further circuit carriers 20, which each have at least one internal contact region 22 and at least one external contact region 24 and are designed as strip-shaped flexible printed circuit boards, and at least two first semiconductor switches HS1 to HS4 and at least two second semiconductor switches LS1 to LS4 are provided. In a step S110, first power terminals 34A of the at least two first semiconductor switches HS1 to HS4 are each arranged and electrically contacted on one of the two internal contact regions 14.1A, 14.1A of the first conductor structure 14 arranged mirror-symmetrically to the central longitudinal axis MLA. In a step S120, first power terminals 34A of the at least two second semiconductor switches LS1 to LS4 are each arranged and electrically contacted on one of the two internal contact regions 16.1A, 16.1B of the second conductor structure 16 arranged mirror-symmetrically to the central longitudinal axis MLA. In a step S130, second power terminals 34B of the first semiconductor switches HS1 to HS4 are each contacted with a common third internal contact region 16.1C of the second conductor structure 16, which contact region is arranged between the first internal contact region 14.1A and the second internal contact region 14.1B of the first conductor structure 14. In a step S140, second power terminals 34B of the second semiconductor switches LS1 to LS4 are each contacted with a common internal contact region 18.1 of a third conductor structure 18, which contact region is arranged between the first internal contact region 16.1A and the second internal contact region 16.1B of the second conductor structure 16. In a step S150, the two further circuit carriers 20 are arranged spatially parallel above the first circuit carrier 10 at opposite edge regions and are connected to the first circuit carrier 10 via soldered connections or welded connections or adhesive connections or sintered connections. In a step S160, control terminals 32 of the first semiconductor switches HS1 to HS4 and of the second semiconductor switches LS1 to LS4 are each contacted with at least one internal contact region 22 of the two further circuit carriers 20.

If necessary, the populated and contacted power module 1 is inserted into a mold tool in a step S170 shown in dashed lines and is overmolded with an enclosure 3 in a molding process in a step S180 shown in dashed lines. During the molding process in step S180, the enclosure 3 is cut out by insert parts in the region of the external contact regions 14.2, 16.2, 18.2 of the first circuit carrier 10, so that the external contact regions 14.2, 16.2, 18.2 of the first circuit carrier 10 can be contacted after removal of the overmolded power module 1A from the mold tool due to the produced cut-outs 5. In a step S190 shown in dashed lines, the enclosure 3 is in each case exposed in regions of the at least one external contact region 24 of the two further circuit carriers 20, so that the contact elements 26 of the external contact regions 24 of the further circuit carriers 20 can be contacted through the exposures 7 produced.

In the exemplary embodiment shown, the contact elements 26 of the external contact regions 24 of the two further circuit carriers 20 are exposed before removal of the overmolded power module 1A from the mold tool. In an alternative exemplary embodiment (not shown) of the method 100 according to the present invention, the overmolded power module 1A is removed from the mold tool first, and then the contact elements 26 of the external contact regions 24 of the two further circuit carriers 20 are exposed.

1-15. (canceled)

16. A power module, comprising:
a first circuit carrier which has an electrically insulating layer, on an upper side of which at least one first conductor structure, having two internal contact regions which are arranged mirror-symmetrically to a central longitudinal axis and on each of which a first power terminal of at least one first semiconductor switch, is arranged and contacted, and at least one second conductor structure having two internal contact regions which are arranged mirror-symmetrically to the central longitudinal axis and on each of which a first power terminal of at least one second semiconductor switch is arranged and contacted, are formed, wherein second power terminals of the first semiconductor switches are each contacted with a common third internal contact region of the at least one second conductor structure, which third internal contact region is arranged between the first internal contact region and the second internal contact region of the at least one first conductor structure, wherein second power terminals of the second semiconductor switches are each contacted with a common internal contact region of at least one third conductor structure, which common internal contact region is arranged between the first internal contact region and the second internal contact region of the at least one second conductor structure; and
at least two further circuit carriers arranged spatially in parallel above the first circuit carrier, and each have at least one internal contact region, at which control terminals of the first and second semiconductor switches are contacted, and each have at least one external contact region which can be electrically connected to an external control circuit, and wherein each of the at least two further circuit carriers is a strip-shaped flexible printed circuit board arranged at opposite edges of the first circuit carrier.

17. The power module according to claim 16, wherein the at least one first conductor structure can be contacted via at least one external contact region with a first supply terminal, and the at least one second conductor structure can be contacted via at least one external contact region with a load terminal, and the at least one third conductor structure can be contacted via at least one external contact region with a second supply terminal.

18. The power module according to claim 16, wherein the at least one first semiconductor switch, which is arranged on the second internal contact region of the at least one first conductor structure, is oriented so as to be rotated by 180° relative to the at least one first semiconductor switch, which is arranged on the opposite first internal contact region of the at least one first conductor structure.

19. The power module according to claim 16, wherein the at least one second semiconductor switch, which is arranged on the second internal contact region of the at least one second conductor structure, is oriented so as to be rotated by 180° relative to the at least one second semiconductor switch, which is arranged on an opposite first internal contact region of the at least one second conductor structure.

20. The power module according to claim 16, wherein the second power terminals of the first semiconductor switches are each contacted via at least one power connection with the third internal contact region of the at least one second conductor structure, and the second power terminals of the second semiconductor switches are each contacted via at least one power connection with the internal contact region of the at least one third conductor structure.

21. The power module according to claim 16, wherein the control terminals of the at least one first semiconductor switch, which is arranged on the first internal contact region of the at least one first conductor structure, and the control terminals of the at least one second semiconductor switch, which is arranged on the first internal contact region of the at least one second conductor structure, are each contacted via signal connections with a common internal contact region of a first further circuit carrier.

22. The power module according to claim 16, wherein the control terminals of the at least one first semiconductor switch, which is arranged on the second internal contact region of the at least one first conductor structure, and the control terminals of the at least one second semiconductor switch, which is arranged on the second internal contact region of the at least one second conductor structure, are each contacted via signal connections with a common internal contact region of a second further circuit carrier.

23. The power module according to claim 16, wherein layouts of the at least two further circuit carriers are identical, and the at least two further circuit carriers are arranged so as to be rotated by 180° relative to one another about a vertical axis.

24. The power module according to claim 17, wherein a first external contact region of a first further circuit carrier is configured to be electrically contacted with a first external contact device that has a contact region with multiple contact elements which can be connected to the contact elements of the first external contact devices via soldered connections or welded connections or adhesive connections or plug connections.

25. The power module according to claim 24, wherein a second external contact region of a second further circuit carrier is configured to be electrically contacted with a second external contact device that has a contact region with multiple contact elements which can be connected to contact elements of the second external contact device via soldered connections or welded connections or adhesive connections or plug connections.

26. The power module according to claim 25, wherein the power module is overmolded by an enclosure, the enclosure having a cut-out in each case in a region of the first and second external contact regions of the first circuit carrier so that the at least one external contact region of the first circuit carrier can be contacted, and an exposure being made in each case in the enclosure in regions of the at least one external contact region of the at least two further circuit carriers so that contact elements of the at least one external contact region of the at least two further circuit carriers are exposed and contactable.

27. A method for producing a power module, comprising the following steps:
forming a first circuit carrier, a layout of the first circuit carrier is mirror-symmetrical to a central longitudinal axis and having an electrically insulating layer, on the upper side of the first circuit carrier at least one first conductor structure, having two internal contact regions which are arranged mirror-symmetrically to the central longitudinal axis, and at least one second conductor structure, having two internal contact regions which are arranged mirror-symmetrically to the central longitudinal axis;
providing two further circuit carriers, which each have at least one internal contact region and at least one external contact region and are configured as strip-shaped flexible printed circuit boards, and at least two first semiconductor switches and at least two second semiconductor switches are provided, wherein first power terminals of the at least two first semiconductor switches are each arranged and electrically contacted on one of the internal contact regions of the at least one first conductor structure that are arranged mirror-symmetrically to the central longitudinal axis, wherein first power terminals of the at least two second semiconductor switches are each arranged and electrically contacted on one of the internal contact regions of the at least one second conductor structure that are arranged mirror-symmetrically to the central longitudinal axis, wherein second power terminals of the first semiconductor switches are in each case contacted with a common third internal contact region of the at least one second conductor structure, the third internal contact region being arranged between a first internal contact region and a second internal contact region of the two internal contact regions of the first conductor structure, wherein second power terminals of the second semiconductor switches are each contacted with a common internal contact region of at least one third conductor structure, the common internal contact region being arranged between a first internal contact region and a second internal contact region of two internal contact regions of the at least one second conductor structure; and
arranging the two further circuit carriers spatially in parallel above the first circuit carrier at opposite edge regions and connecting the two further circuit carriers to the first circuit carrier via soldered connections or welded connections or adhesive connections or sintered connections, wherein control terminals of the first and second semiconductor switches are each contacted with at least one internal contact region of the two further circuit carriers.

28. The method according to claim 27, wherein the power module is inserted into a mold tool and is overmolded with an enclosure in a molding process, an enclosure being cut out by insert parts in a region of external contact regions of the first circuit carrier during a molding process so that the external contact regions of the first circuit carrier can be contacted after removal of the overmolded power module from the mold tool due to the produced cut-outs, and the enclosure being exposed in each case in regions of the at least one external contact region of the two further circuit carriers so that the contact elements of the external contact regions of the two further circuit carriers can be contacted through the produced exposure.

29. The method according to claim 28, wherein the external contact regions of the two further circuit carriers are exposed before removal of the overmolded power module from the mold tool.

30. The method according to claim 28, wherein the external contact regions of the two further circuit carriers are exposed after removal of the overmolded power module from the mold tool.
